(19) United States
(12) Patent Application Publication
(10) Pub. No.: US 2007/0212938 A1
(43) Pub. Date: Sep. 13, 2007

(54) Connection cable between printed circuit boards of a portable terminal

(75) Inventor: Young-Shik Shin, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/700,553

(22) Filed: Jan. 31, 2007

(30) Foreign Application Priority Data
Feb. 1, 2006 (KR) 10-2006-0009709

(51) Int. Cl. H01R 9/05

(52) U.S. Cl. 439/579

(57) ABSTRACT

Provided is a connection cable between Printed Circuit Boards (PCBs) of a portable terminal having a plurality of PCBs to connect signals of the plurality of PCBs and to connect provided ground planes. The connection cable includes at least one coaxial cable electrically connected between the PCBs for providing a ground plane for a stable high-speed signal interface between the PCBs and a cable connector included in the PCBs for electrically connecting the coaxial cable and providing another ground plane connected to the ground plane of the coaxial cable.

### PRIORITY

This application claims priority under 35 U.S.C. §119 to an application entitled “Connection Cable Between Printed Circuit Boards of Portable Terminal” filed in the Korean Intellectual Property Office on Feb. 1, 2006 and assigned Serial No. 2006-9709, the contents of which are incorporated herein by reference.

### BACKGROUND OF THE INVENTION

1. Field of the Invention

The present invention relates generally to a connection cable between Printed Circuit Boards (PCBs) of a portable terminal having a plurality of PCBs, and in particular, to a connection cable between PCBs of a portable terminal having a plurality of PCBs to connect signals of the plurality of PCBs and to connect provided ground planes.

2. Description of the Related Art

Generally, portable terminals keep pace with high sensitivity, miniaturization, and lightness of electronic parts. Bar-type cellular phones were commonly used as first-generation cellular phones and flip-type cellular phones were commonly used as second-generation cellular phones. At present, flip-type cellular phones and folder-type cellular phones are widely used as third-generation cellular phones.

Wearable phones worn on a body part and clothes, such as watch-type cellular phones worn on a user's wrist have been developed.

The assignee of present application developed a portable terminal including a plurality of boards to improve the portability and wearing sense of a wearable phone. Such a phone is disclosed in Korean Patent Application No. 2005-41508 filed in the Korean Intellectual Property Office on May 18, 2005.

As shown in FIG. 1, a portable terminal 10 disclosed in Korean Patent Application No. 2005-41508 includes a plurality of PCBs 12 and a plurality of housings 11 having the PCBs 12 therein. A hinge device 13 in such a manner connects the housings 11 such a manner that they can be rotated and bent. The PCBs 12 include a Liquid Crystal Display (LCD) 14, a keypad 15, and an antenna (not shown).

As shown in FIG. 2, the portable terminal 10 includes the plurality of PCBs 12, in each of which various parts are mounted. A plurality of connectors 16 are mounted in opposite sides between the PCBs 12 and Flexible PCBs (FPCBs) 17 electrically connect the connectors 16 between the PCBs 12.

The FPCBs 17 between the connectors 16 includes signal lines for transmitting various communication signals and signals for controlling various parts and power source lines for power supply.

The number of signal lines and power source lines provided in the FPCBs 17 is closely related to the size of each of the PCBs 12. The size of each of the PCBs 12 is closely related to the wearing sense of a wearable phone. In other words, as the size of each of the PCBs 12 decreases, the wearing sense of the wearable phone is improved, but the number of PCBs 12 increases and thus the number of connections between the PCBs 12 also increases.

The increase in the number of connections between the PCBs 10 leads to an increase in the length of signal lines. Since, the thickness of the signal lines is limited due to the connections between the PCBs 12, both the inductance and AC resistance component of the signal lines increase in the wearable phone, unlike a general portable terminal.

Simply, since all parts exist in a single board in a general portable terminal, using wide signal lines or minimizing the length of signal lines can reduce parasitic components of a signal structure such as inductance or AC resistance. However, in a portable terminal including a plurality of PCBs, since parasitic components of signal lines increase for the reason described above, stable signals cannot be provided to a device and a large voltage drop is caused.

High performance cannot be expected from high-speed signals that are sensitive to those features when connections are implemented using FPCBs because there is no way to handle various external noises.

In a grounding process that is essential for providing a stable signal, sufficient ground planes cannot be secured between the PCBs with conventional FPCBs due to the limited number of pins. The FPCBs should be designed in such a manner that the PCBs can be folded, causing a difficulty in a designing process and degrading durability against external shocks.

Such problems also occur in a ground structure, and thus a connection structure between a power source and a ground, which has low inductance and AC resistance, is required to ensure the performance of a portable terminal having a plurality of PCBs.

### SUMMARY OF THE INVENTION

It is, therefore, an object of the present invention to provide a connection cable between PCBs of a portable terminal having a plurality of PCBs to connect signals of the PCBs of the portable terminal and to connect provided ground planes, thereby reducing noise in high-speed signals and thus guaranteeing stable signal connection.

It is another object of the present invention to provide a connection cable between PCBs of a portable terminal having a plurality of PCBs, in which ground planes are provided in a coaxial cable and a connector for a stable signal interface between PCBs included in a wearable phone, thereby achieving durability improvement and shaping easiness that cannot be expected from a conventional FPCB.

To achieve the above and other objects, there is provided a connection cable between PCBs of a portable terminal having a plurality of PCBs. The connection cable includes at least one coaxial cable electrically connected between the PCBs for providing a ground plane for a stable high-speed signal interface between the PCBs and a cable connector included in the PCBs for electrically connecting the coaxial cable and providing another ground plane connected to the ground plane of the coaxial cable.

### BRIEF DESCRIPTION OF THE DRAWINGS

The above and other objects, features and advantages of the present invention will become more apparent from the following detailed description when taken in conjunction with the accompanying drawings in which:

FIG. 1 is a perspective view of a wearable phone according to the conventional art;

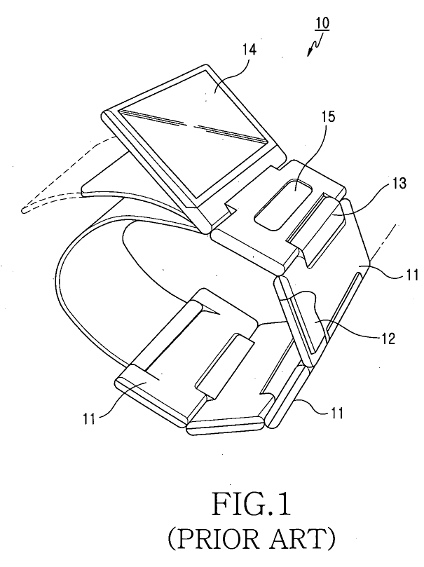

FIG. 2 illustrates a portable terminal including a plurality of PCBs according to the conventional art;

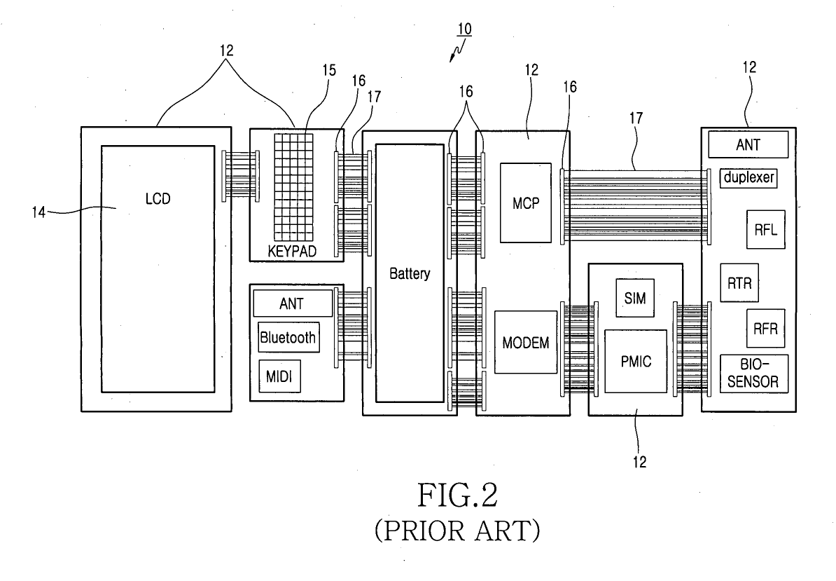

FIG. 3 is a perspective view of a coaxial cable included in a connection cable between Printed Circuit BoardS (PCBs) of a portable terminal according to the present invention;

FIG. 4 illustrates a state where a connection cable between PCBs of a portable terminal according to the present invention is used;

FIG. 5 is an enlarged view of a portion A of FIG. 4; and

FIG. 6 illustrates a state where a coaxial cable and a cable connector that are included in a connection cable between PCBs of a portable terminal according to the present invention are connected.

### DETAILED DESCRIPTION OF THE PREFERRED EMBODIMENT

A preferred embodiment of the present invention will now be described in detail with reference to the annexed drawings. In the following description, a detailed description of known functions and configurations incorporated herein has been omitted for conciseness.

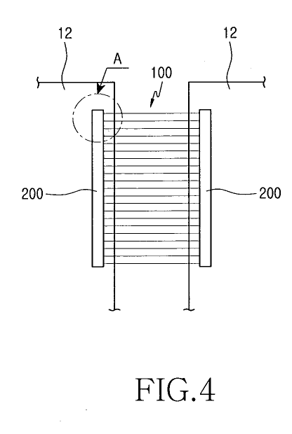

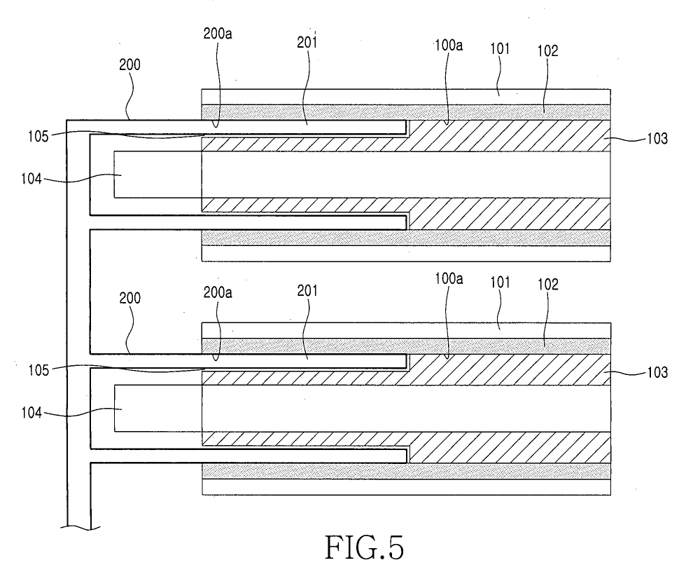

As shown in FIGS. 4 and 5, a connection cable between PCBs 12 of a portable terminal having a plurality of PCBs 12 includes at least one coaxial cable 100 and cable connectors 200. The coaxial cable 100 is electrically connected between the PCBs 12 to provide a cable ground plane 100a for a stable high-speed signal interface between the PCBs 12 and the cable connector 200 is included in each of the PCBs 12 to electrically connect the coaxial cable 100 and to provide a connector ground plane 200a connected to the cable ground plane 100a.

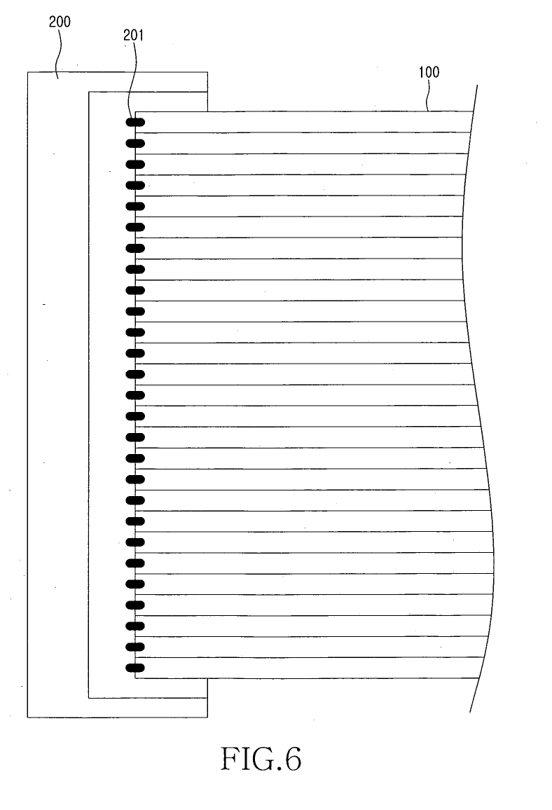

As shown in FIGS. 5 and 6, the cable ground plane 100a is disposed in the coaxial cable 100 for stable signal connection and the connector ground plane 200a is disposed in the cable connector 200 for stable signal connection.

As shown in FIGS. 5 and 6, the cable ground plane 100a of the coaxial cable 100 and the connector ground plane 200a of the cable connector 200 are electrically connected to each other and a plurality of ground planes 100a and 200a are provided.

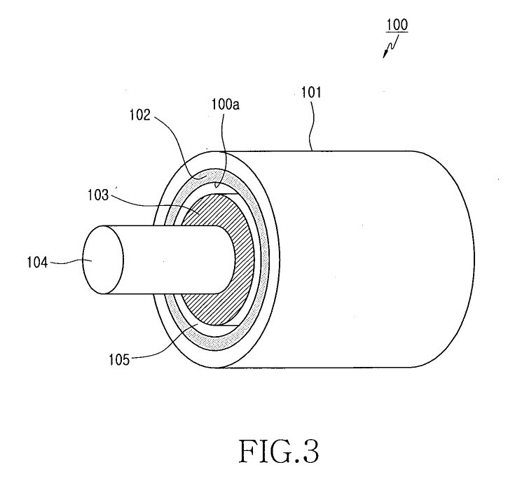

As shown in FIG. 3, the coaxial cable 100 includes a covering 101, a signal connection line 102, an insulating material 103, a signal line 104, and a connection terminal 105. The covering 101 protects the coaxial cable 100 from an external shock. The signal connection line 102 is included inside the covering 101 to provide the cable ground plane 100a. The signal line 104 is included inside the insulating material 103 to connect electric signals. The connection terminal 105 is combined with a pin 201 included in the cable connector 200 and is included between the signal connection line 102 and the insulating material 103 to electrically connect the cable ground plane 100a with the connector ground plane 200a.

The insulating material 103 is made of a synthetic resin material such as plastic. The signal connection line 102 and the signal line 104 are made of a metal material such as copper.

The connection terminal 105 takes the form of a groove recessed to a predetermined depth into the coaxial cable 100.

The operation of the connection cable between the PCBs of a portable terminal according to the present invention will be described in more detail with reference to FIGS. 3 through 6.

As shown in FIGS. 4 and 5, a connection cable for a wearable phone including the plurality of PCBs 12 includes at least one coaxial cable 100 and cable connectors 200.

As shown in FIG. 3, the coaxial cable 100 includes the covering 101 for protecting the coaxial cable 100 from an external shock, and the signal connection line 102 for providing the cable ground plane 100a, the insulating material 103, and the signal line 104 inside the covering 101.

As illustrated in FIG. 6, the connection terminal 105 is included between the signal connection line 102 and the insulating material 103 to be combined with the pin 201 of the cable connector 200 and to electrically connect the cable ground plane 100a with the connector ground plane 200a.

In this state, as shown in FIG. 5, the PCBs 12 are electrically connected to each other using the coaxial cable 100. At this time, the connection terminal 105 of the coaxial cable 100 is combined with and electrically connected to the cable connector 200 of the PCB 12.

Since the connection terminal 105 includes a groove recessed to a predetermined depth into the coaxial cable 100, the pin 201 of the cable connector 200 is inserted into the groove of the connection terminal 105 for connection.

Thus, as shown in FIG. 6, the cable ground plane 100a and the connector ground plane 200a are electrically connected to each other and in this manner, the plurality of ground planes 100a and 200a are connected between the PCBs 12.

As such, the PCBs 12 in the wearable phone secure a plurality of ground planes for a stable signal interface between the PCBs 12, thereby contributing to miniaturization of the phone. Moreover, by using a coaxial cable having superior durability, durability improvement and shaping easiness that cannot be expected from a conventional FPCB can be achieved.

While the invention has been shown and described with reference to a certain preferred embodiment thereof, it will be understood by those skilled in the art that various changes in form and details may be made therein without departing from the spirit and scope of the invention.

What is claimed is:

1. A connection cable between Printed Circuit Boards (PCBs) of a portable terminal having a plurality of PCBs, the connection cable comprising:
at least one coaxial cable electrically connected between the PCBs for providing a ground plane for a stable high-speed signal interface between the PCBs; and
a cable connector included in the PCBs for electrically connecting the coaxial cable and providing another ground plane connected to the ground plane of the coaxial cable.

2. The connection cable of claim 1, wherein a cable ground plane is disposed in the at least one coaxial cable.

3. The connection cable of claim 1, wherein a connector ground plane is disposed in the cable connector.

4. The connection cable of claim 2, wherein the cable ground plane and a connector ground plane disposed in the cable connector are electrically connected to each other and a plurality of ground planes are provided.

5. The connection cable of claim 3, wherein a cable ground plane disposed in the coaxial cable and the connector ground plane are electrically connected to each other and a plurality of ground planes are provided.

6. The connection cable of claim 1, wherein the at least one coaxial cable comprises:
a covering exposed to the outside;
a signal connection line for providing the ground plane inside the covering;
an insulating material inside the signal connection line;
a signal line inside the insulating material; and
a connection terminal included between the signal connection line and the insulating material for being combined with a pin included in the cable connector and electrically connecting the cable ground plane with the connector ground plane.

7. The connection cable of claim 6, wherein the connection terminal is recessed to a predetermined depth into the coaxial cable.

8. The connection cable of claim 6, wherein the insulating material is made of a synthetic resin material.

9. The connection cable of claim 6, wherein-the signal connection line and the signal line are made of a metal material.

10. A connection cable between Printed Circuit Boards (PCBs) of a portable terminal having a plurality of PCBs, the connection cable comprising:
at least one cable electrically connected between the PCBs for providing a ground plane for a stable high-speed signal interface between the PCBs; and
a cable connector included in the PCBs for electrically connecting the cable and providing another ground plane connected to the ground plane of the cable.
